(19) United States
(12) Patent Application Publication
(10) Pub. No.: US 2006/0166433 A1
(43) Pub. Date: Jul. 27, 2006

(54) Recessed collar etch for buried strap window formation without poly2

(76) Inventors: Min-Soo Kim, Sandston, VA (US); Jonathan Davis, Shanghai (CN); Debra Heier Arnold, Richmond, VA (US); Robert Fuller, Mechanicsville, VA (US)

Correspondence Address: BRINKS HOFER GILSON & LIONE, P.O. BOX 10395, CHICAGO, IL, 60610, US

(21) Appl. No.: 11/043,756

(22) Filed: Jan. 26, 2005

(51) Int. Cl. H01L 21/8242

(52) U.S. Cl. 438/243; 438/386

(57) ABSTRACT

A method for manufacturing a trench capacitor with a reduced resistance in a buried strap window for use in a memory circuit such as a dynamic random access memory circuit may be realized by reducing the number of polysilicon layers that are deposited. The method includes the deposition of a collar material followed by a dry etch of the collar material. The collar material is etched away from the top region leaving a layer of collar material on the wall of the trench between the surface of the first polysilicon layer filling the bottom of the trench and the upper region where the collar material was removed. The second polysilicon layer may be deposited after the collar material has been etched for making contact to other devices.

### BACKGROUND

1. Technical Field

The present invention relates to the process of fabricating trench capacitors for memory circuits in semiconductor substrates, and in particular, the fabrication of trench capacitors with improved conductivities in the buried strap window.

2. Background Information

Dynamic Random Access Memory (“DRAM”) devices are important components in a computer system. Very few computer systems can operate without DRAM memory and as the need for memory has increased, the size of the memory cells has shrunk placing more memory cells in a given area on a wafer. One of the techniques for attaining the higher densities is the use of trench capacitors.

Trench capacitors were developed as a way to increase capacitance without utilizing the valuable surface area that would otherwise be occupied by surface capacitors. Trench capacitors allow for an increase in the area of a capacitor by utilizing the surface of the trench walls that are formed into the substrate. The area available for the trench capacitor may depend upon the depth of the trench and the tools available to properly process the materials that may be applied at those depths.

The following equation shows the relationship of area to capacitance of a capacitor:
C=εA/t (1)
where ε is the dielectric constant of the insulator between the plates of the capacitor, t is the thickness of the insulating material acting as the dielectric, and A is the area of the capacitor. Since the trench capacitor can be formed into the substrate, the walls of the trench may be utilized to form one of the plates of the capacitor. Thus, the trench provides the needed area for forming the capacitor thus preserving valuable real estate on the surface of the substrate or wafer for additional circuit elements.

As the line-width design rule have approached 110 nm, it is |important that the process not affect the designed electrical characteristics of the devices. This was especially true for the materials that make up the various devices. As the devices became smaller, any defect in the material may have catastrophic results for the device or the overall circuit. Therefore, the polysilicon that fills the trench is expected to have good conductivity characteristics. In the current design of a buried strap (“BEST”) window, there may be three or more levels of polysilicon as the process for forming the trench capacitor progresses. Each polysilicon layer that fills the trench may be utilized as sacrificial material that protects other areas of the device during formation.

The follow-on polysilicon layer that is formed establishes an interface with the underlying layer. The interface between the layers may exhibit defects. In some instances, the under-lying layer may form a thin native oxide as it reacts with oxygen or with other airborne materials and chemicals. The combination of the defects and the native oxide at the interface will work in concert to raise the electrical resistance of the material when a subsequent layer is deposited. Even though the interface is very thin, as the dimensions of the devices are reduced, the interface plays a larger role in the circuit resistance of the memory circuit as the percentage of the interface increases with respect to the amount of overall material.

Therefore, it is advantageous to reduce the number of interfaces and provide a good conduction path in the connection to the trench capacitor. When the oxide forms on the polysilicon layer interfaces in the trench capacitor, the material exhibits an increased resistance. The resulting oxide, even though thin, may have catastrophic results in materials that abide by the 110 nm design rules. Such an oxide becomes a major percentage of the conductive material and may increase the resistance of the connections to the trench capacitors thus reducing the access time of the overall memory circuit. Therefore, a need exists to modify the process to reduce the number of polysilicon layers that have interfaces where oxides and defects may form.

### BRIEF SUMMARY

The embodiments disclosed herein provide an improved process for forming a trench capacitor that may eliminate a sacrificial polysilicon layer and an interface in the trench capacitor. In particular, this process finds applications in dynamic random access memory (DRAM) circuits that use the BuriEd STrap (BEST) cell architecture. The process provides for an alternative etching method that removes a collar oxide layer from the top of the trench capacitor and eliminates what is commonly referred to as the poly2 layer.

In one embodiment, the process for forming the trench capacitor includes forming the trench in the substrate. Upon formation of the trench, the wall of the trench is coated with an arsenic silicate glass to make the surface of the trench highly conductive during a drive diffusion. This highly conductive layer may provide a node for forming the first plate of the trench capacitor. Once the node is formed, the node nitride may be deposited on the walls of the trench to form the dielectric of the capacitor. A filling material, polysilicon, will be deposited on the wafer filling the trench with polysilicon. The polysilicon may be doped to provide a high conductivity so that the polysilicon may form the second plate of the trench capacitor. The polysilicon may be deposited by a chemical vapor deposition (CVD) process.

Once deposited, the polysilicon may be etched so that a recess is formed in the polysilicon layer that fills the trench. The polysilicon that was deposited on the surface of the wafer may be removed during the etching process. The recess that is formed by removing the polysilicon in the trench exposes nitride on the wall of the trench. The exposed nitride will be removed and the remaining polysilicon in the trench forms a mask protecting the nitride that will become the dielectric for the capacitor from the etching process.

Once the unwanted nitride is removed from the wall of the trench, a collar or collar material may be deposited inside the recess of the trench and over the surface of the wafer by using another CVD process. The collar material may be formed from a silicon oxide that is deposited in the CVD process. The excess oxide may be etched away using a reactive ion etching process or other equivalent dry etching process capable of removing the oxide from the surface of the wafer. The oxide may be removed from the trench wall surface to a depth of approximately 200 nm from the surface of the wafer. Below that level, the collar remains on the wall. Another nitride layer, the buried strap nitride may be deposited on the wall of the trench where the excess oxide was removed.

After the removal of the excess collar material, the recess of the trench may now be back-filled with another layer of polysilicon, the polysilicon covering the collar oxide and making contact to the second plate of the trench capacitor. Further contact may be made to this polysilicon layer at a later time for connecting the trench capacitor to the device or devices comprising the memory cell. Standard processes may be used for forming the switching devices and providing electrical contact to the trench capacitor during follow-on processes.

### BRIEF DESCRIPTION OF THE DRAWINGS

The application can be better understood with reference to the following drawings and description. The components in the figures are not necessarily to scale, emphasis instead being placed upon illustrating the principles of the invention. Moreover, in the figures, like referenced numerals designate corresponding parts throughout the different views.

FIG. 1 is a diagram of a trench capacitor.

FIG. 2 is a process flow diagram for forming a trench capacitor.

FIG. 3 is a diagram of the trench with the node.

FIG. 4 is a diagram of a trench with the node nitride.

FIG. 5 is a diagram showing the recess after the first polysilicon layer is etched.

FIG. 6 is a diagram of a trench capacitor showing the etched collar.

FIG. 7 is a diagram of a trench capacitor with the second polysilicon fill.

### DETAILED DESCRIPTION OF THE DRAWINGS AND THE PRESENTLY PREFERRED EMBODIMENTS

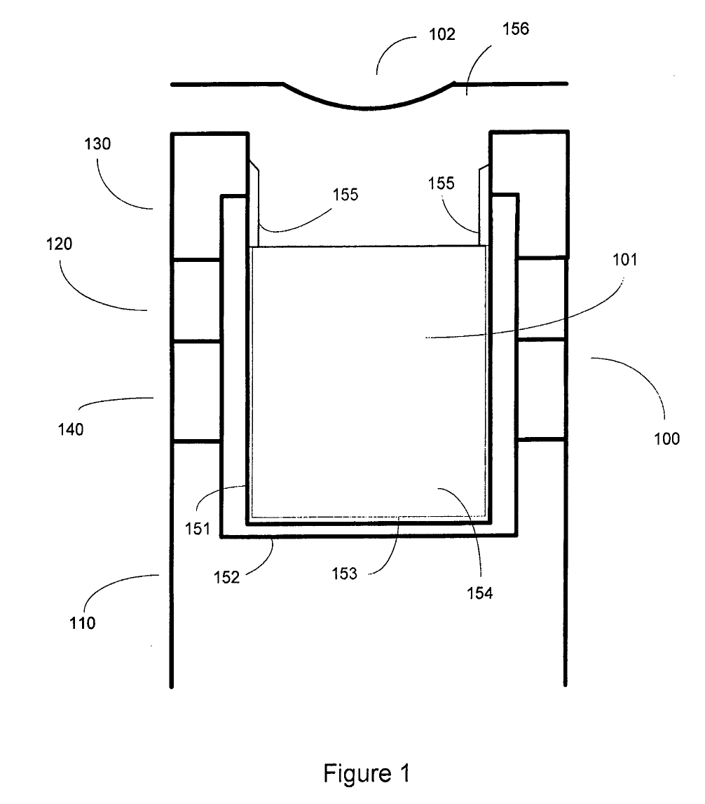

A trench capacitor 100 that interfaces with a BuriEd Strap (“BEST”) window 101 is shown in FIG. 1. FIG. 1 is a partial cross-sectional view of a semiconductor wafer or substrate 110 showing a memory cell employing the trench capacitor 100 as a charge storage element.| The trench capacitor 100 is formed using a process where the capacitor 100 may demonstrate improved RC time constants due to the reduced resistance in the BEST window 102 |architecture. In the prior art, a BEST window 102 is formed using a three polysilicon layer deposition technique. The second layer or the “poly2 layer” functions as a sacrificial layer in the three layer process. This new process eliminates the “poly2” layer. Instead, the trench capacitor 100 is formed from a process that uses a dry etching process to delineate a collar material, replacing the wet etching process and the need for the “poly2” layer. The collar material may be an insulating material that includes silicon dioxide, silicon nitride or a hafnium oxide or any other suitable insulating material used in a semiconductor process. In a preferred embodiment, a silicon dioxide may be used and is commonly referred to as a collar oxide.

The dry etching process may exhibit preferential etching of the exposed materials. For example, the etching action may preferentially etch in one direction and may preferentially etch one material over another. Therefore, the dry etch process may eliminate the need to provide the sacrificial “poly2” layer that provides a protective mask, shielding the collar material deep inside the trench from the wet etch process. The inclusion of such a sacrificial layer results in extra processing steps as well as an extra interface. The interface is the region between the two layers where the surface of the previously deposited layer and the newly deposited layer come together both mechanically and electrically. The interface may include a native-oxide layer and/or defects, between the sacrificial polysilicon mask layer and the polysilicon contact fill layer. The dry etching process eliminates the sacrificial polysilicon layer and the associated interface.|

By eliminating the interface, the defects and the thin native-oxide that reside at the interface are eliminated also. Thus, the deposited polysilicon contact material may exhibit improved conductivity with the removal of these potential resistances. It is intended in this structure that the polysilicon also form a BEST structure. The BEST structure is a buried strap that may make contact to the transistors and bit and word lines. With the improvement in the conductivity of the polysilicon, an improvement in the RC-time constant may be attained allowing for a higher data rate in the memory circuit.

The RC time constant represents the amount of time required to charge or discharge a capacitor through a resistance. The longer the time constant, the longer the time period to access a memory cell. The RC time constant is inversely proportional to the speed with which the circuit will operate. With the reduced size of the circuit architectures, any small increase in resistance of the polysilicon can have implications to the access time of the circuit.

Polysilicon is silicon that has no real structure to its arrangement. On a microscopic scale, some portions of the material may exhibit crystalline quality but the overall arrangement of the layer may be more amorphous than crystalline. Polysilicon may be formed by an epitaxial or chemical vapor deposition (“CVD”) technique forming small or microscopic crystals that generally combine in an unarranged fashion.

In FIG. 1, the trench capacitor 100 is formed in a semiconductor wafer or substrate 110. For most memory cells, a silicon substrate 110 may be used but a trench capacitor 100 may be formed in a semiconductor wafer of any material. The substrate 110 may have one, two or more semiconductor layers disposed on the surface of the substrate of different conductivities. By way of example, an n-type layer 140 is formed on the substrate 110 with a p-type layer 120 and an n-type layer 130 formed on top of the n-type layer 140, respectively in FIG. 1. The respective layers are doped to n-type or p-type using appropriate dopant materials in conventional processes.

The trench| 101 is formed in the wafer 110. The inner wall 151 of the trench will be processed to form a doped layer 152 that may exhibit a high conductivity. The high conductivity region 152 will extend into the surface of the wall 151 functioning as a node or one of the plates of the capacitor. A dielectric material 153 will be deposited over the surface of the wall 151 forming a dielectric region| of the trench capacitor. The dielectric material 153 may be a nitride layer that is also known as the node nitride layer. The dielectric material 153 may include other materials such as oxides of silicon or materials with high dielectric constants that may be suitable for capacitors. A layer 154, composed of polysilicon and highly conductive, will be deposited on the dielectric material 153 forming the second plate of the trench capacitor 100. The collar oxide 155 is deposited and formed on the upper regions of the trench wall 151 some distance below the surface of the wafer and above the recessed polysilicon layer 154 that fills the bottom region of the trench. A second polysilicon layer 156 is deposited on the wafer 110 and fills the remainder of the trench 101 while making both a mechanical and electrical contact to the first polysilicon layer 154. The second polysilicon layer forms the buried strap window that provides an electrical connection between the inner plate| of the trench capacitor 100 and the remainder of the devices that will form the memory cell.

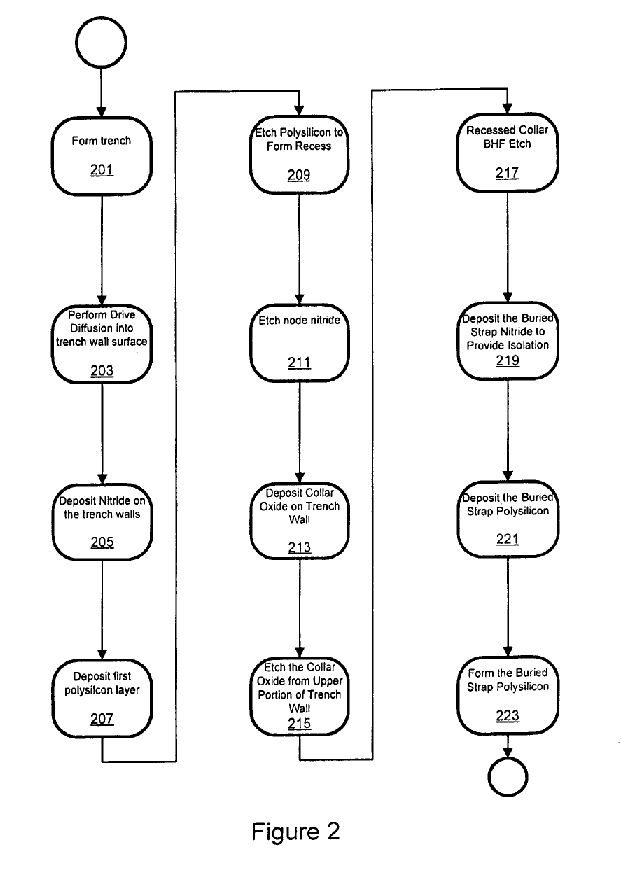

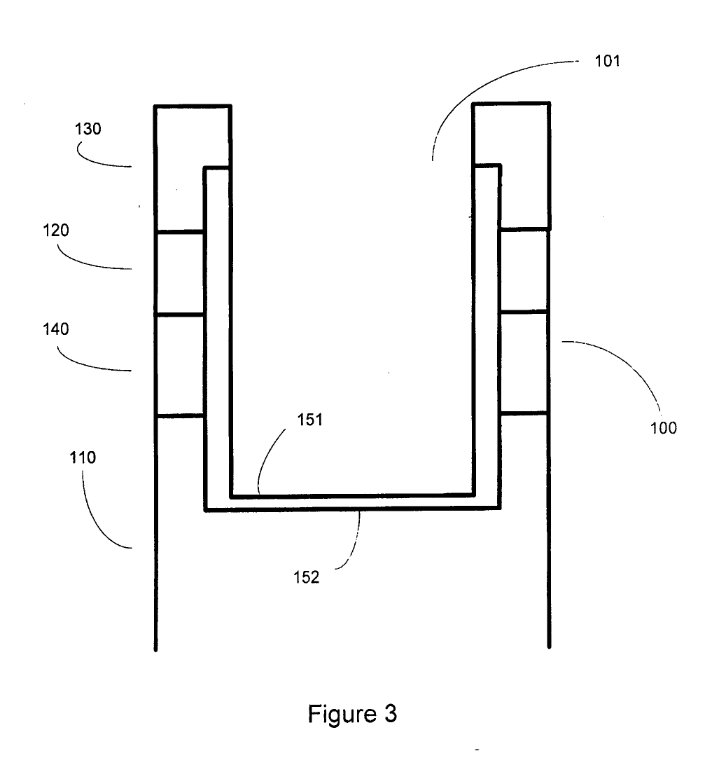

The process for forming the trench capacitor 100 may be described by the flow diagram in FIG. 2. The process will be described in conjunction with FIGS. 3-7, which are cross sectional views of the trench capacitor 100 illustrating the steps in the process. A silicon substrate 110 is used in the preferred embodiment, but other wafers such as sapphire, silicon carbide, gallium arsenide, or other compound semiconductor wafers may be included. Although memory circuits are the intended devices to be developed with this process, other circuitry may be arranged where the use of a trench capacitor would be suitable.

As discussed previously, layers of varying conductivities or compositions may be formed on the surface of the substrate 110. The compositions of the layers may take the form of silicon and/or germanium when a silicon wafer is utilized or may include other alloys of the previously mentioned substrate materials when those materials are used as the substrate. Other processing layers (not shown) also may be formed on the surface of the wafer. These layers may include photo-resist, silicon nitride, silicon dioxide or other suitable layers that may be sacrificial and mask the surface and other features formed on the substrate as the substrate is processed.

In the process of FIG. 2, the trench 101 is formed in the substrate 110, block 201|. The resulting trench is portrayed in FIG. 3. By way of example, the trench may penetrate and intersect with an n-type layer 130, a p-type layer 120 and another n-type layer 140 which may or may not be the substrate 110. These layers may form an n-p-n bipolar junction transistor.

In other embodiments (not shown), the trench 101 may penetrate materials that might form a p-n-p or even a p-n-p-n transistor. The form of the transistor depends upon the conductivity type and the arrangement of the semiconductor layers that intersect with the trench.

A heavily-doped semiconductor layer 152 may be formed by diffusing, block 203, a doping material from a source such as arsenic silicate glass (“ASG”) into the wall 151 of the trench. This highly conductive layer 152 is illustrated in FIG. 3. The ASG deposited on the wall 151 contains arsenic and during the drive diffusion acts as an infinite source of arsenic. The high temperatures will cause the arsenic to diffuse from the source material and into the wall 151 of the trench and provide a region of n-type conductivity in the wall 151 of the trench 101. When initially deposited, the ASG will cover the entire wafer. It will be removed from all areas other than the walls of the trench where the drive diffusion is intended to occur. In other applications, a p-type layer may be formed by depositing a different source material heavily concentrated with the appropriate p-type atom that will be diffused. Regardless of the dopant type used, the formation of this heavily-doped layer 152 may effectively short the parasitic transistor by forming one highly-doped layer through all of the layers of varying conductivity, thus eliminating the transistor layers near the trench capacitor and making the parasitic transistor ineffective. The parasitic transistor can cause charge leakage from the trench capacitor 100, reducing its effectiveness as a charge storage device.

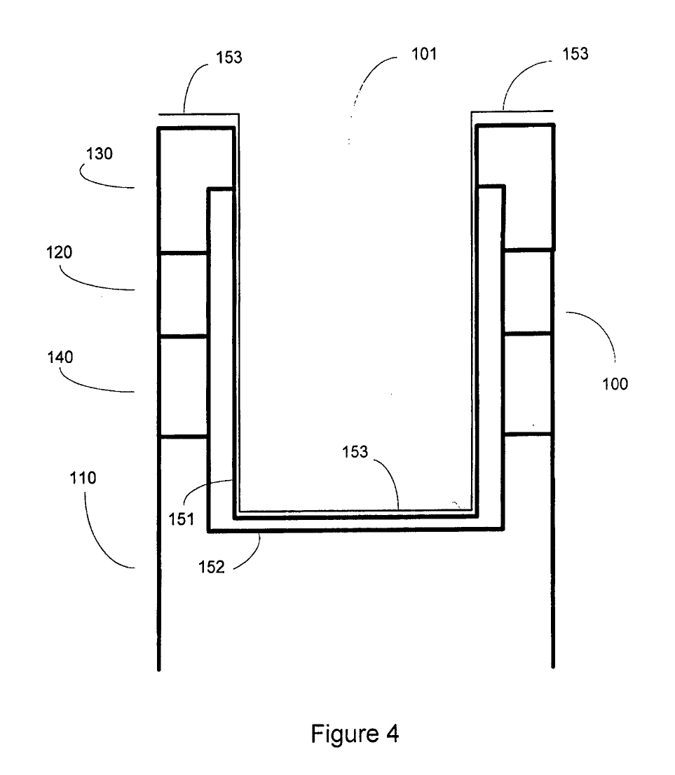

The heavily-doped layer 152 also forms a node that may be used as the “outer plate” electrode of the trench capacitor 100. The dielectric for the trench capacitor 100 is formed over the node 152| by a dielectric material 153 that is deposited, block 205, in a CVD process step as shown in FIG. 2. During the deposition of the layer, the dielectric material 153 is deposited over the surface of the wafer as well as on the side wall 151 of the trench 101. This layer is featured in FIG. 4. Prior to the nitride deposition at block 205, some embodiments of this process also may include the deposition of other protective layers over the surface of the wafer. The inclusion of the protective layers in the process is deemed to be within the scope of this invention.

When the capacitor dielectric material is the node nitride 153, the node nitride 153 may have pinholes or microscopic voids after the deposition step 205 is complete. Preferably, the dielectric region of the capacitor will have a high dielectric constant. Therefore, further processing may remove these defects and improve the quality of the nitride 153 that forms the dielectric material. Such techniques may include a re-oxidation process. Re-oxidation is a steam process, whereby the unattached silicon in the nitride may be oxidized and the pinholes closed. This process step is sometimes referred to as a densification of the nitride. Other techniques for improving or densifying the nitride layer may include an anneal or rapid thermal anneal.

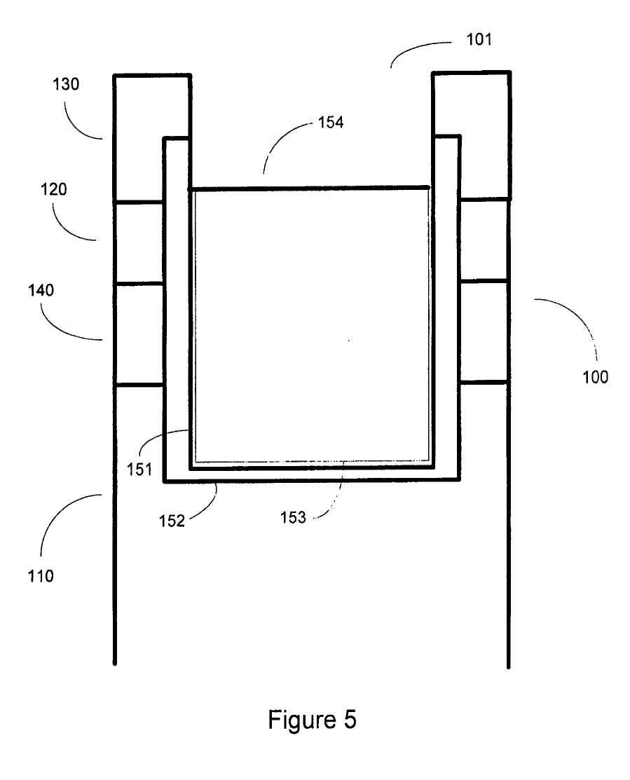

In forming the dielectric region of the trench capacitor 100, the node nitride 153 is removed from all other areas of the wafer except the lower portion of the trench wall 151. The node nitride 153 may define the active area of the trench capacitor 100 in conjunction with the node 152. Preferably, the node nitride 153 remaining after the etching process will cover the node 152 region forming the outer capacitor plate electrode as shown in FIG. 5. However, the area of the node nitride 153 to be preserved for forming the capacitor dielectric may require a covering or masking with a protective layer before the node nitride 153 is etched.

Therefore after the node nitride 153 is deposited in the trench 101, a polysilicon layer 154 is deposited, block 207, on the wafer. The polysilicon layer 154 will perform two functions. In the first function, the polysilicon layer 154 provides the second or “inner” electrode plate of the trench capacitor 100. In the second function, the polysilicon layer 154 provides the masking material for etching the node nitride 153 that forms dielectric region of the capacitor. The polysilicon deposition initially covers the entire wafer and fills the trench 100. The polysilicon may be deposited in a low pressure chemical vapor deposition process (“LPCVD”). The LPCVD process is a low-pressure process utilizing a heated susceptor that holds and heats the substrate to a particular process temperature. In LPCVD, the heated susceptor provides the energy necessary to crack the source materials to provide the deposition of materials on the wafer surface.

The process may be modified to increase the deposition rate by using a plasma-enhanced chemical vapor deposition process (“PECVD”). The PECVD method is still performed at a low pressure, however a high frequency electromagnetic wave, generally in the radio frequency (“RF”) range, may be generated to create a plasma in the source gases. The plasma enhances the energy for breaking down or “cracking” the source material to grow the polysilicon layer 154. The energy and heat from the susceptor also may assist in dissociating the source material molecules. A source material for the polysilicon layer may include silane, disilane or other silane compounds. The CVD process will coat the surface of the wafer and the trench with polysilicon.

Since the polysilicon layer may be conductive to provide electrical contact as the “inside plate” of the capacitor, a dopant may be added to the growth process to provide the necessary conductivity. The polysilicon layer 154 may be doped as it is deposited using a source that may contain arsenic or phosphorus or other equivalent dopant-type sources. The dopant source may be introduced to the LPCVD chamber in trace amounts depending upon the amount of doping that is required in the polysilicon layer.

Once the polysilicon layer 154 is deposited at block 207, the layer will be etched, block 209 and removed from the surface of the wafer, forming a recess in the trench, with the surface of the polysilicon layer 154 in the trench some distance below the surface of the wafer. The etching of the polysilicon may be performed in a hydrochloric wet etch process. When the etching at block 209 of the polysilicon 154 is completed, the node nitride 153 forming the dielectric material on the wall 151 of the trench 101 is exposed. The exposed node nitride 153 may be etched, block 211, and the polysilicon layer 154 will cover and protect the node nitride 153 that forms the dielectric of the trench capacitor 100. At this point in the process, the structure may appear like the exemplary representation in FIG. 5.

In the trench 101, where the dielectric material 153 has been removed, a collar material 155 may be deposited at block 213 to provide electrical isolation between a later deposited polysilicon BEST structure and the surrounding elements on the substrate. The collar material 155 may be deposited, block 213 on all of the exposed surfaces of the wafer. In the preferred embodiment, the collar material may be silicon dioxide. The collar material 155 may be etched later using a dry etching technique, block 215.|

Preferably, the dry etching process of block 215 is a reactive ion etching (“RIE”) process, but other dry etching processes such as an inductively coupled plasma may be utilized to perform the etching of the collar oxide 155. An inductively coupled plasma is an etching process that selectively etches one type of material while leaving another material relatively unscathed. In another method, a reactive ion beam etching tool uses an ion beam to remove the material from the wafer. The ion beam etching process directs ions towards the material to be removed by bombarding the material with ions. In the reactive ion etch process, it is intended that the process combine the chemical etching principle with the ion beam etching principle to remove the collar material 155 from the surface of the wafer and from the top portion of the wall of the trench. The reactive ion etch is not predominantly an ion beam etching tool but exhibits some of those characteristics.

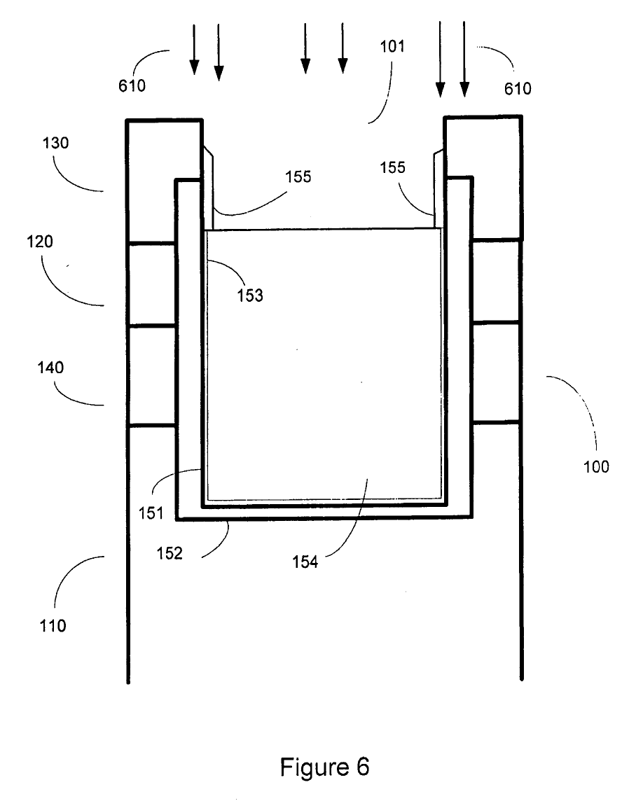

The dry etching process of block 215 is a selective etch in that only the targeted material type will be removed during the etching process. The reactive ion etching process may preferentially etch one material over another. Therefore, a masking layer may not be required to protect materials exposed in the trench. Because of the tendency toward directional etching, the collar material 155 or oxide deposited on the wall 151 of the trench may not need to be protected, especially away from the surface of the wafer. Only the collar material 155 exposed at the top of the trench may be etched since it is perpendicular to the travel direction of the ions as shown by the arrows 610 in FIG. 6. In reality, some etching of the exposed collar material 155 may take place. However, the etch rate may be vastly smaller than the etch rate of material that is directly perpendicular to the plasma at the surface of the wafer.

Since the reactive ion etch process of block 215 tends to be selective, the process may remove silicon dioxide and leave the polysilicon relatively unscathed. Therefore, in a preferred embodiment where the collar material 155 is silicon dioxide, the material 155 may be removed down to a particular depth into the trench without adversely affecting the polysilicon. In this process, it is intended that the collar material 155 be removed to a depth of approximately 200 nm. The exact dimensions of the depth may vary depending upon the trench capacitor 100 to be formed. A representation of the final configuration of the collar oxide is shown in FIG. 6.

Since the reactive ion etch process may be selective, a protective or sacrificial layer may not be required to protect the collar material 155 in this process. In a wet etch process, the collar material 155 would be otherwise exposed to the etching solution and would require masking. The dry etching process of block 215 may eliminate the need for the sacrificial layer, such as the “poly 2” layer that is used in the wet etch process. Since the sacrificial layer is eliminated from the preferred embodiment of the process, the follow-on cleaning of the wafer and/or the exposed layer before the next deposition step removes the possibility of contamination from the cleaning chemicals, especially at any resulting interface.

The dry etching process may be followed by a buffered Hydrofluoric Acid (“BHF”) etch, block 217. This BHF etch of block 217 is the pre-cleaning step before a nitride process that is incorporated to provide electrical isolation at the top of the trench. After the BHF etching step 217, the nitride layer (not shown) is deposited at block 219. This nitride layer may be referred to as the buried strap nitride layer.

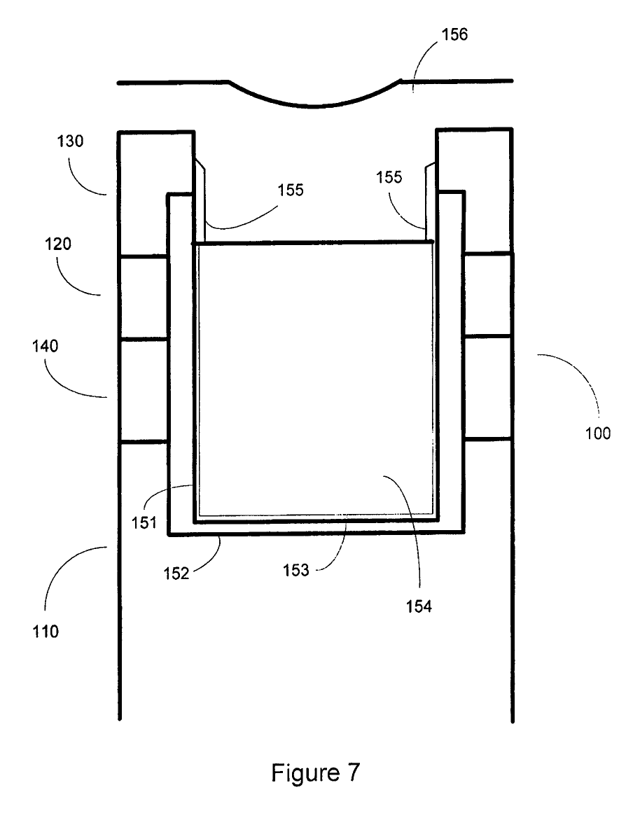

A second polysilicon layer 156 is deposited at block 221 and this layer will function as the buried strap window 10|2. This polysilicon layer 156 is deposited over the entire wafer. During the deposition, the polysilicon 156 may fill the recess in the trench 101 and cover the collar material 155. As with the first polysilicon layer 154, this layer also may be deposited in an LPCVD process. The deposition of this layer is represented in FIG. 7.

The second polysilicon fill material 156 that is deposited, block 221 in the recess may provide a contact to the first polysilicon layer 154. Preferably, the layer 156 is heavily-doped to provide good conductivity. The layer 156 may be doped during the deposition much in the same way the first polysilicon layer 154 may have been doped. Such source materials may include phosphine or one of the phosphine organo-metallics to lessen the toxicity risk of phosphine. A phosphine source material may be used to make the polysilicon layer n-type, but the source material is not limited to phosphine sources. Other sources such as arsenic source materials may be used. Further, other dopant sources may be utilized to make the polysilicon material p-type if it is desired.

Once the polysilicon layer 156 has been deposited, the layer may be planarized using a chemical-mechanical polishing (“CMP”) process. The CMP process is a polishing process that removes material from the surface of the wafer using a slurry with an abrasive and an etching solution mixed. If the slurry does not contain an abrasive material, most likely the pad used for polishing the wafer will have an abrasive.

The CMP process will remove a pre-determined amount of the polysilicon from the surface. When the polysilicon was deposited, it formed a layer over the features that were formed on the wafer. Some of the features had recesses, other features were raised above the surface. The growth in those areas varied forming non-planar features. The CMP process tends to flatten the surface so that subsequent processes may be carried out without encountering a non-planarized surface.

From this step onward, other processing steps may be performed to incorporate the active devices for the memory circuit as well as the metallization that may be required to connect the capacitor to the active devices. Many of the processing steps may vary as the trench capacitor 100 may be incorporated into different types of circuits.

It is therefore intended that the foregoing detailed description be regarded as illustrative rather than limiting, and that it be understood that it is the following claims, including all equivalents, that are intended to define the spirit and scope of this invention.

We claim:

1. A method for making a trench capacitor comprising:
forming a trench in a substrate where the trench penetrates a doped semiconductor layer and extends into the substrate;
modifying the electrical characteristics of a wall of the trench to form a capacitor plate electrode;
disposing a nitride on the wall of the trench to form a trench capacitor dielectric;
filling the trench with a first polysilicon fill layer that covers the nitride;
etching the first polysilicon fill layer to form a first recess in the trench;
removing the excess nitride from the wall of the trench above the first polysilicon layer;
disposing a collar material on the wall of the trench above the first polysilicon layer;
etching the collar material using a dry etch process to remove the collar material from the surface of the substrate and to selectively remove the collar material from the upper portion of the wall of the trench; and
disposing a second polysilicon layer on the wafer filling the recess with the second polysilicon layer to cover the remaining collar material.

2. The method of claim 1, where the first polysilicon layer is a conductive material.

3. The method of claim 1, where the trench capacitor dielectric is a dielectric having a high dielectric constant.

4. The method of claim 1, further comprising the step of disposing the collar material using a low pressure chemical vapor deposition (LPCVD) process.

5. The method of claim 1, where the dry etch process is a reactive ion etch process.

6. The method of claim 1, where the dry etch process removes the collar material from the wall of the upper portion of the trench to a depth of about 200 nm from the top of the trench.

7. The method of claim 1, further comprising the step of removing a native oxide from the first polysilicon layer.

8. The method of claim 1, further comprising the step of disposing a buried strap nitride layer on the wall of the trench above the collar material.

9. The method of claim 1, where the second polysilicon layer is a conductive material.

10. The method of claim 1, further comprising the step of using a chemical mechanical polishing (CMP) process on the disposed second polysilicon layer to planarize the surface of the substrate.

11. The method of claim 1, further comprising the step of forming an electrical contact to the second polysilicon layer.

12. The method of claim 1, further comprising the step of forming a transistor for a memory cell.

13. The method of claim 12, further comprising the step of forming an electrical connection between the transistor and a contact to the second polysilicon layer on the trench capacitor.

14. The method of claim 1, where the collar material is silicon dioxide.

15. The method of claim 1, where the collar material is silicon nitride.

16. The method of claim 1, where the collar material is hafnium oxide.

17. A method for the manufacture of trench capacitors for improving the conductivity of the buried strap window comprising:
forming a trench in a substrate;
doping a wall or portion of a wall of the trench so that a capacitor electrode plate is formed;
disposing a dielectric material over the capacitor electrode plate;
filling the trench with a polysilicon material so that the dielectric material is covered;
etching a recess in the first polysilicon layer exposing the dielectric material in an upper portion of the trench and leaving an unetched portion of the first polysilicon layer in a bottom region of the trench that covers the dielectric material in the bottom region;
stripping the exposed dielectric material from the wall of the trench above the unetched portion of the first polysilicon layer;
disposing a collar material on the wall of the trench above the unetched portion of the first polysilicon layer;
etching the collar material from a surface of the wafer and a top portion of the wall of the trench using a dry etch process exposing the wall in the upper regions of the trench with an amount of the collar material remaining between the exposed wall of the trench and the surface of the first polysilicon layer; and
filling the recess in the trench above the unetched portion of the first polysilicon layer where the remaining collar material in the trench is covered with a second polysilicon layer.

18. The method of claim 17, where the dry etch process removes the collar material from the wall of the upper portion of the trench to a depth of about 200 nm from the top of the trench.

19. A method for the manufacture of a trench capacitor where the conductivity of the buried strap window is improved in a process comprising:
etching a first polysilicon layer from a surface of a wafer and forming a recess in a trench where the first polysilicon wafer fills a bottom region of the trench and a node nitride layer previously disposed on a wall of the trench is exposed above the first polysilicon;
etching the exposed node nitride layer from the wall;
disposing a collar material on the wall of the trench where the node nitride was removed;
etching the collar material from the wall in a dry etch process from a region below the surface of the wafer, the collar material remaining on the wall from the surface of the first polysilicon layer in the lower region of the trench to the region below the surface of the wafer; and
filling the recess with a second polysilicon layer covering the collar material in the trench.

20. The method of claim 19, where the etching of the collar material from a region below the surface is about 200 nm below the surface.
